(19) United States
(12) Patent Application Publication
(10) Pub. No.: US 2010/0244125 A1
(43) Pub. Date: Sep. 30, 2010

(54) POWER SEMICONDUCTOR DEVICE STRUCTURE FOR INTEGRATED CIRCUIT AND METHOD OF FABRICATION THEREOF

(75) Inventors: Jan Sonsky, Leuven (BE); Gerhard Koops, Kessel-Lo (BE); Rob Van Dalen, Bergeijk (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/294,820

(22) PCT Filed: Mar. 26, 2007
(86) PCT No.: PCT/IB2007/051043

§ 371 Date: Sep. 26, 2008

(30) Foreign Application Priority Data
Mar. 28, 2006 (EP) 06111830.3

(51) Int. Cl. H01L 29/78; H01L 21/336

(52) U.S. Cl. 257/330; 438/270; 257/E29.262; 257/E21.41

(57) ABSTRACT

A power semiconductor device comprises a conductive gate, provided in an upper part of a trench (11) formed in a semiconductor substrate (1), and a conductive field plate, extending in the trench, parallel to the conductive gate, to a depth greater that the conductive gate. The field plate is insulated from the walls and bottom of the trench by a field plate insulating layer that is thicker than the gate insulating layer. In one embodiment, the field plate is insulated within the trench from the gate. Impurity doped regions of a first conductivity type are provided at the surface of the substrate adjacent the first and second sides of the trench and form source and drain regions, and a body region (7) of second conductivity type is formed under the source region on the first side of the trench (11). The conductive gate is insulated from the body region (7) by a gate insulating layer. A method of making the semiconductor device is compatible with conventional CMOS processes.

The present invention relates to a semiconductor device and more particularly to a power semiconductor device structure that can be included in an integrated circuit device and a method of fabrication thereof.

Power integrated circuits provide a power device integrated with other integrated circuit devices, such as CMOS logic devices, on a single semiconductor substrate.

The design and fabrication of integrated circuit devices comprising power devices in combination with other types of semiconductor devices face numerous challenges for maximizing device performance and minimizing processing costs. For example, the optimal power device is the so-called “TrenchMOS”, which has a vertical structure, whereas the structure of other semiconductor devices such as CMOS logic devices is typically lateral. In particular, optimal discrete power devices have a vertical arrangement whereby the source and drain are provided on opposing major surfaces of the substrate and current flow, controlled by a trenched-gate, is vertical, perpendicular to the first major surface. In contrast, in CMOS logic devices the source and drain are formed adjacent the first major surface and spaced laterally by a channel region over which the gate structure is formed such that current flow is lateral, parallel to the first major surface. In consequence of these structural differences, as well as differences in dimensions, the conventional fabrication processes used to form vertical power devices and lateral CMOS devices differ considerably.

To address these conflicting requirements, it is conventional to employ lateral DMOS power devices instead of vertical TrenchMOS devices to allow integration of power and logic devices. In lateral DMOS or extended drain MOSFET power devices, the source and drain are provided at the same first major surface as the CMOS devices and the current flow is lateral. However, DMOS power devices consume considerable die area due to their lateral configuration and the limits on their lateral size due to resistances associated with the channel and drift regions. In particular, a reduction in the channel length of DMOS devices is difficult to achieve due to the necessary high well (and/or anti-punch through) doping levels, which limits the achievable breakdown voltage. Equally problematic is the lateral scaling of the drift region, which is determined by the maximum electric field that can be handled by the device (at most 20V/micron for optimized devices). A reduction in the lateral scale of the drift region becomes increasingly difficult for breakdown voltages above about 30V. Moreover, the thick gate oxide required to accommodate high voltage applications prohibits reduction of gate/channel length substantially below 1 micron for reasonable threshold voltage.

The use of vertical power devices, i.e. TrenchMOS, allows lateral scaling and thus consumes less area, but the fabrication process thereof requires the formation of buried N+/P+ layers and formation of connections to them, which is not readily compatible with current CMOS processing.

U.S. Pat. No. 5,723,891 proposes a trench DMOS transistor structure having laterally spaced source and drain regions on a first major substrate surface and a gate formed in a trench between the source and drain. The trench has a non-uniform isolation lining, whereby the lining is thicker on the drain side of the trenched-gate. The thin lining on the source side of the trenched-gate thus defines the channel. Current flow is both lateral and vertical, being vertical from source to channel, lateral beneath the trenched-gate into the drain drift region, and vertical from the drift region to the drain. This structure enables a reduction in cell pitch when compared with conventional DMOS power devices but the method of its fabrication is not readily compatible with conventional integrated circuit fabrication processes. Moreover, the switching speed of the trench DMOS power device of U.S. Pat. No. 5,713,891 is not optimized.

The present invention seeks to provide an improved power device structure for use in integrated circuit applications, including high voltage applications, and a fabrication method, which is more conveniently implemented in combination with a standard integrated circuit (e.g. CMOS) process.

According to a first aspect, the present invention provides a semiconductor device comprising a semiconductor substrate having a first major surface; a trench extending from the first major surface into the substrate; first and second impurity doped regions of a first conductivity type at respective first and second opposing sides of the trench adjacent the first major surface; a body region of a second conductivity type, opposite to the first conductivity type, below the first impurity doped region on only the first side of the trench; a drift region of the first conductivity type, below the body region and the second impurity doped region, the trench terminating in the drift region; a conductive gate insulated from the body region by a gate insulator, and a conductive field plate in the trench, the field plate extending into the trench substantially parallel to the conductive gate to a depth greater than or equal to the depth of the conductive gate, wherein the field plate is insulated from the drift region in the trench by a field plate insulating layer, and wherein the thickness of the field plate insulating layer is substantially greater than the thickness of the gate insulator.

In one embodiment, the field plate insulating layer is at least three times the thickness of the gate insulator, and typically greater than about five times its thickness. For example, the field plate insulating layer may have a thickness in the range of about 50 to 800 nm for a typical gate insulator thickness in the range of about 3 to 15 nm for a device having a gate operational voltage between 2 and 10V. For a device requiring a breakdown voltage of 100V, it is contemplated that the field insulating plate layer may be at least 500 nm in thickness for trench dimensions (width/depth) of up to a few microns and a conventional gate insulator thickness. For larger breakdown voltages, the ratio between the field plate insulating layer thickness and gate insulating thickness would be even greater.

According to a second aspect, the present invention provides a method for making a semiconductor device, comprising: forming a trench in a first major surface of a semiconductor substrate, the trench having first and second opposing sides; lining the trench with a first insulating layer having a first thickness; filling the trench with a conductive material; forming first and second impurity doped regions of a first conductivity type adjacent the first major surface at the respective first and second sides of the trench; forming a body region of a second conductivity type, opposite to the first conductivity type, only on the first side of the trench, the body region extending to a first predetermined depth from the first major surface; forming a sub-trench extending to a second predetermined depth from the first major surface and having a first sidewall adjacent the body region; lining the first sidewall of the sub-trench with a second insulating layer having a second thickness, which is substantially less that the first thickness, and filling the sub-trench with a conductive material.

Typically, the second predetermined depth is substantially the same as the first predetermined depth.

According to a third aspect, the present invention provides a method for fabricating a power integrated circuit comprising a power device and at least one other semiconductor device, using the method in accordance with the second aspect of the present invention.

Further optional features will be apparent from the following description and accompanying claims.

Embodiments of the present invention will now be described, by way of example, with reference to the accompanying drawings, in which:

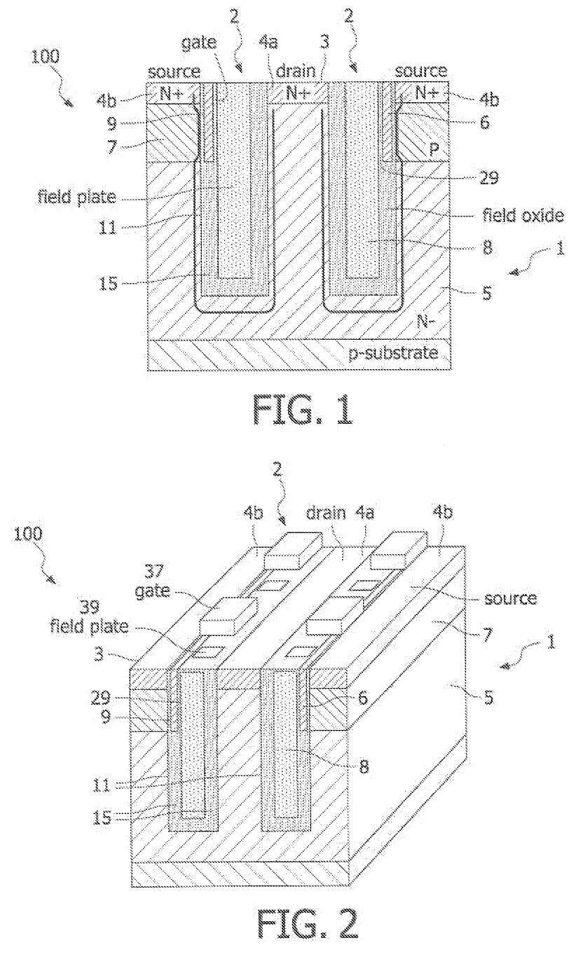

FIG. 1 is a cross section of an NMOS power transistor cell, comprising a pair of NMOS transistors, in striped configuration in accordance with an embodiment of the present invention;

FIG. 2 is a perspective view of the NMOS power transistor cell of FIG. 1;

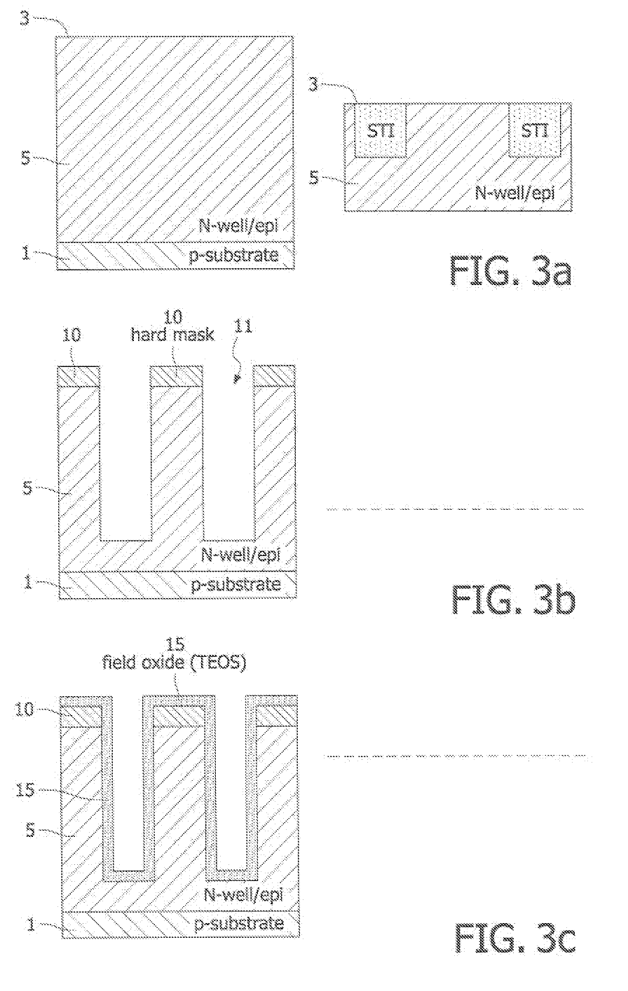

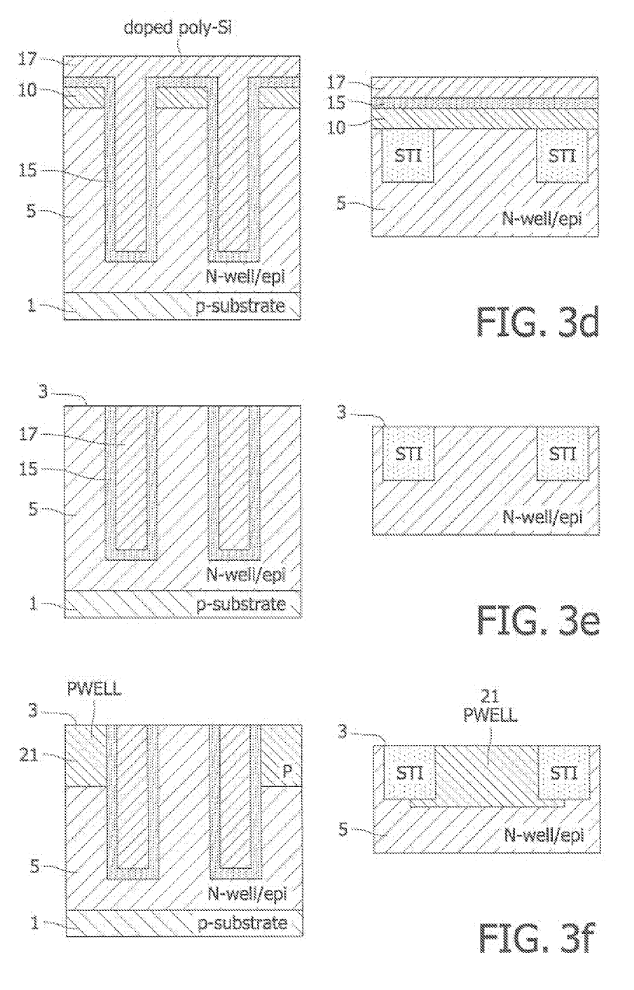

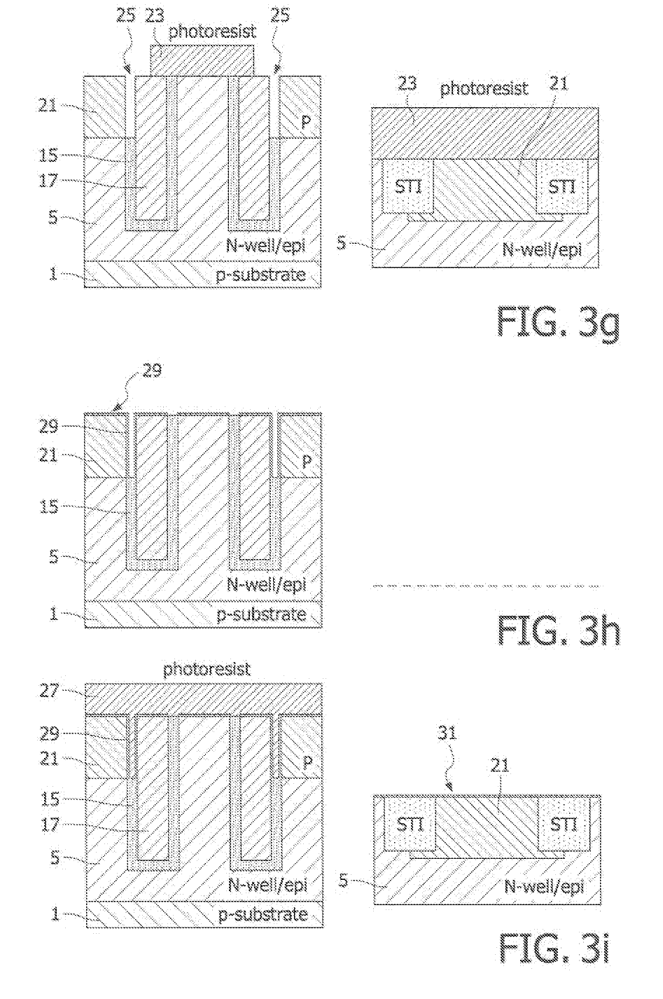

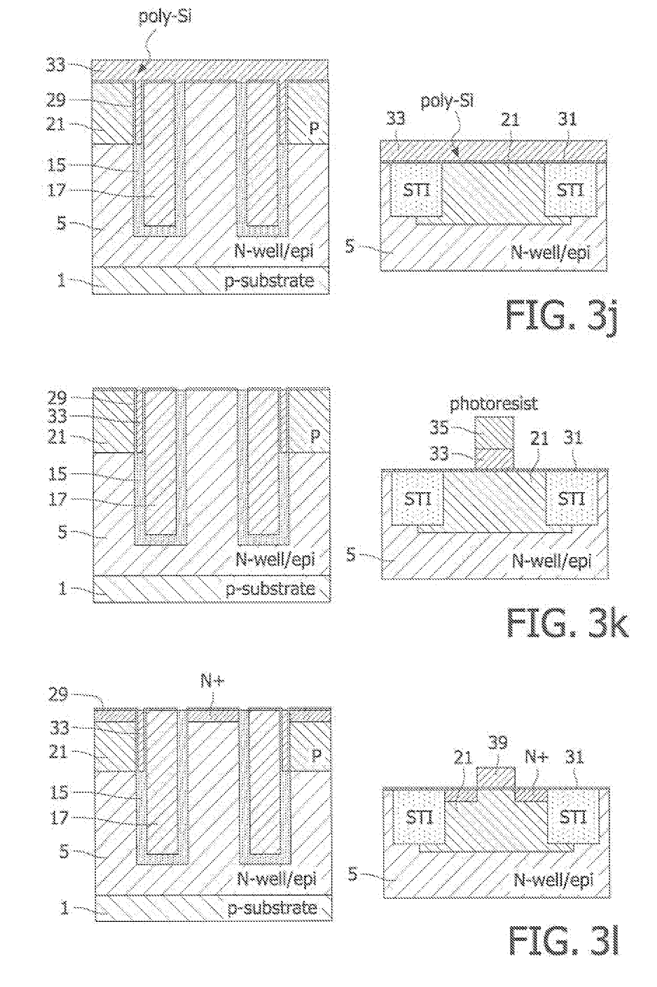

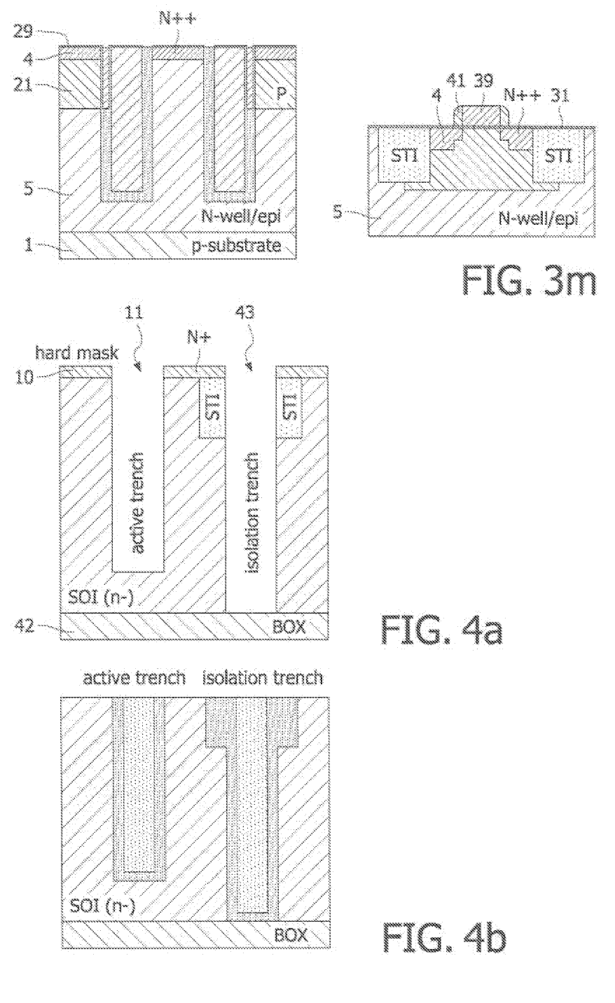

FIGS. 3a to 3m illustrate cross sectional views of portions of a combined power transistor and CMOS integrated circuit during stages of a method for fabricating the power transistor in accordance with an embodiment of the present invention;

FIGS. 4a and 4b illustrate cross sectional views during stages of a method for fabricating a power transistor on an SOI substrate in accordance with another embodiment of the present invention;

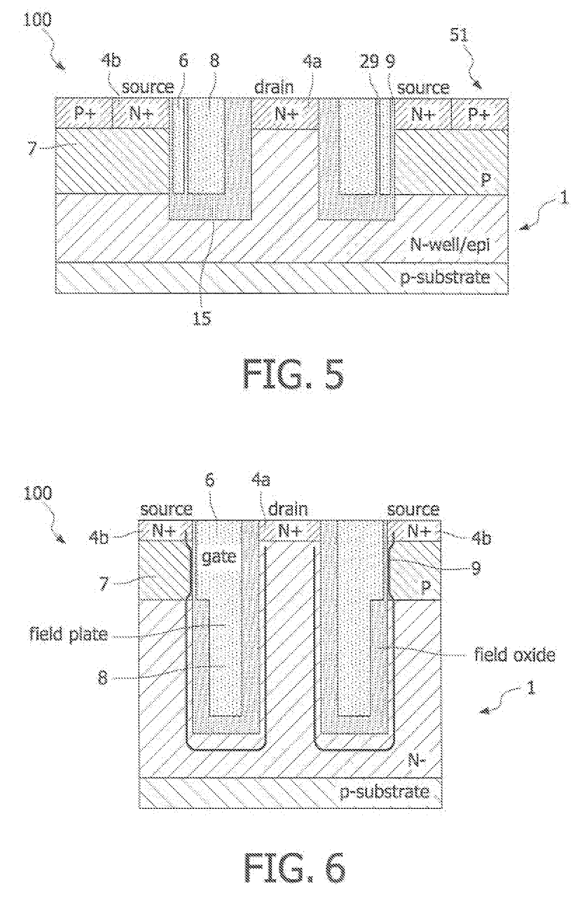

FIG. 5 is a cross section of an NMOS transistor cell, similar to FIG. 1, in accordance with another embodiment of the present invention;

FIG. 6 is a cross section of an NMOS transistor cell, similar to FIG. 1;

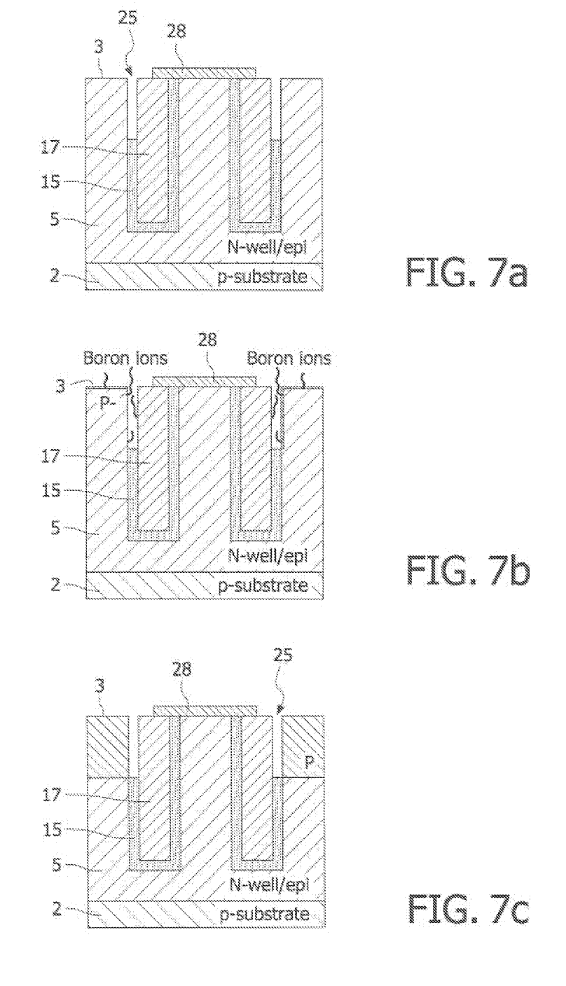

FIGS. 7a to 7c illustrate cross sectional views during stages of a method for fabricating a power transistor in accordance with an embodiment of the present invention;

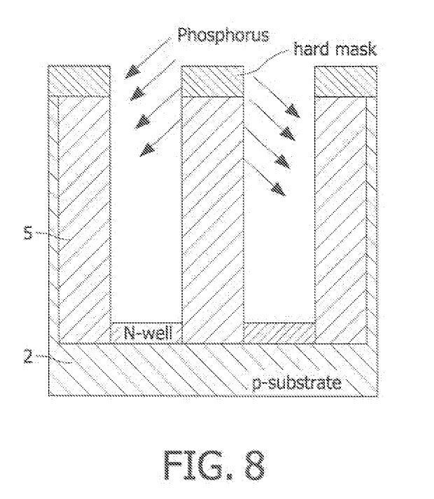

FIG. 8 illustrates a cross sectional view during one stage of a method for fabricating a power transistor in accordance with another embodiment of the present invention;

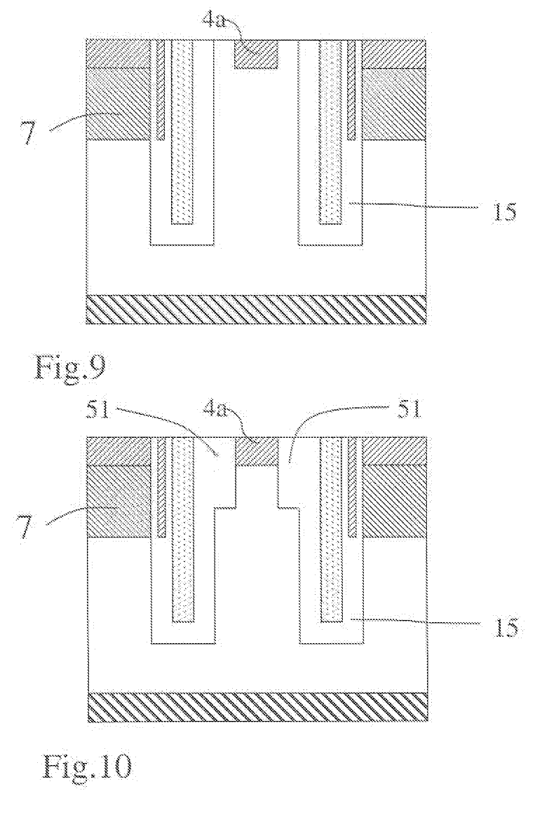

FIG. 9 is a cross section of an NMOS transistor cell, similar to FIG. 1, in accordance with another embodiment of the present invention;

FIG. 10 is a cross section of an NMOS transistor cell, similar to FIG. 1, in accordance with a further embodiment of the present invention;

FIG. 11 is a cross section of an NMOS transistor cell, similar to FIG. 1, in accordance with another embodiment of the present invention;

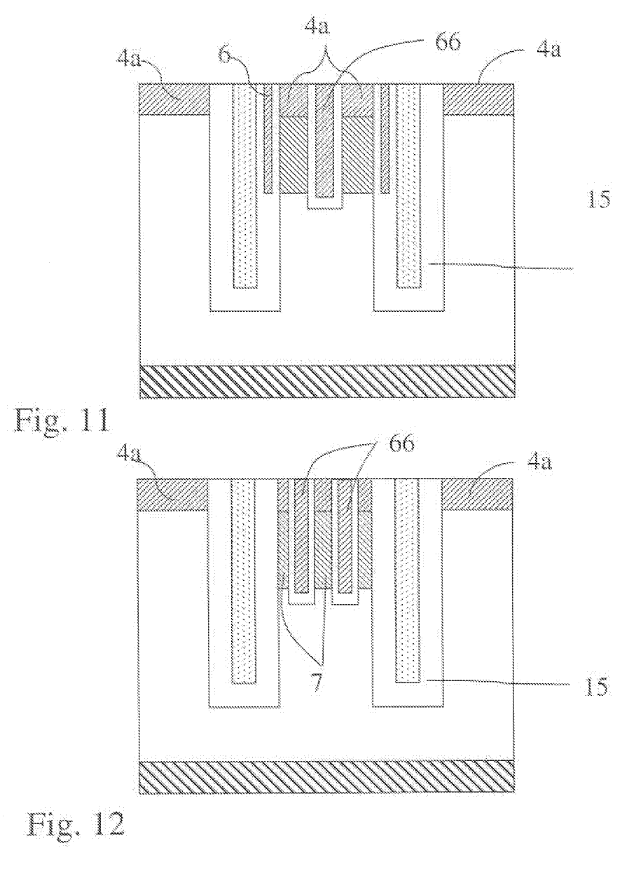

FIG. 12 is a cross section of an NMOS transistor cell in accordance with a further embodiment of the present invention;

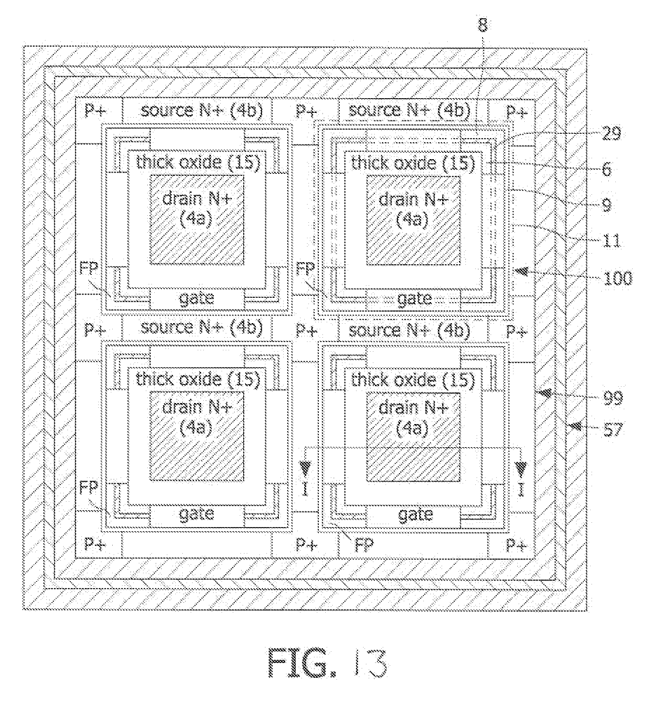

FIG. 13 is a plan view of an array of square power transistor cells of a power device, forming part of an integrated circuit device, in accordance with another embodiment of the present invention; and

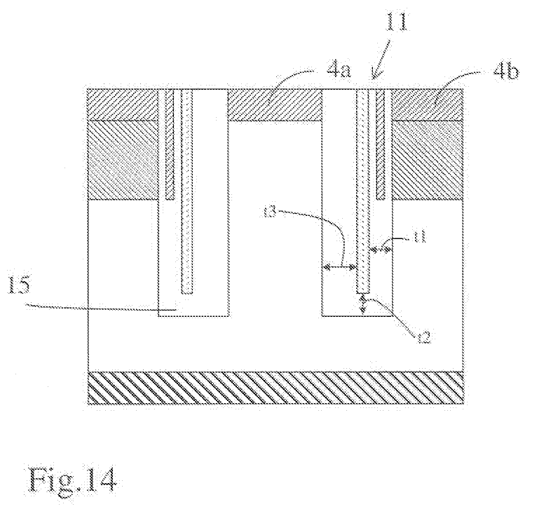

FIG. 14 is a cross section of an NMOS transistor cell in accordance with a further embodiment of the present invention.

The drawings are for illustrative purposes only, and are not to scale. Similar elements in the drawings have been accorded like reference numerals.

FIGS. 1 and 2 show a cell 100 of a power semiconductor device, in turn forming a part of an integrated circuit device, in accordance with an embodiment of the present invention. The drawings show a pair of NMOS power transistor devices 2, having a striped configuration, formed in an n-type doped well 5 provided in a p-type silicon semiconductor substrate 1, in accordance with the embodiment. The skilled person will appreciate that the transistor devices may equally be a PMOS device, in which case the conductivity types of the elements will be reversed.

The substrate 1 has an upper, first major surface 3, and the n-well 5 is provided adjacent the first major surface 3. In one embodiment, the n-well may be formed as an n-type epitaxial layer on a p-type monocrystalline substrate, such that the upper surface of the epitaxial layer forms the first major surface of the substrate 1. In another embodiment, the n-well 5 may be formed by implanting n-type dopants into the p-type substrate 1. A pair of parallel trenches 11 extends substantially perpendicularly from the first major surface 3 to a first depth into the n-well 5 and forms a mirror-image pair of striped power transistors 2. Each transistor 2 has a first side and a second side, and it will be appreciated that the transistors are orientated such that like sides of adjacent transistors face each other in mirror image fashion to form a symmetrical transistor cell 100. In the illustrated example, the second sides of the transistors 2 face each other. A heavily doped n-type region 4 adjacent the first major surface 3 and extending to a second depth from the surface 3 forms a common drain region 4a between the opposing second sides of the trenches 11 of the mirror image transistor pair 2 and a source region 4b to opposite, first sides of the trenches 11. A p-type body region 7 extending to a third depth from the substrate surface 3, which is less that the first depth and greater that the second depth, is provided below the source regions 4a on the opposite, first sides of the trenches 11 of the mirror image transistor pair. It should be noted that the p-type body region 7 is not formed below the common drain region 4a, between the opposed second sides of the trenches 11 of the transistor pair, but only below the source region 4b on the first sides of the trenches 11.

Each of the trenches 11 contains an insulated conductive gate 6 and an insulated field plate 8 as shown in FIG. 1. In particular, a doped polysilicon gate 6 extends to substantially the third depth, this being substantially the depth of the p-body region, in each trench 11 adjacent to the source region thereof, and being insulated from the source region and p-body region, on the first side of the trench, by a relatively thin gate insulator 9. A doped polysilicon field plate 8 extends in each trench, substantially parallel to the gate 6, to a depth greater than the depth of the polysilicon gate 6 in this embodiment, and is insulated in the trench from the surrounding n-well region 5 (the second side, the bottom and the lower part of the first side of the trench) by a relatively thick insulating layer 15. In an alternative embodiment, illustrated in FIG. 5 and described in more detail below, the field plate 8 may extend to substantially the same depth as the gate 6. In the embodiment of FIGS. 1 and 2, the field plate 8 is additionally insulated from the gate 6 by a relatively thin insulating layer 29 and separate contacts 37, 39 are respectively provided for the gate 6 and the field plate 8 in each trench 11, as shown in FIG. 2.

The power transistor structure thus formed has a Trench DMOS structure, with laterally spaced source 4b and drain 4a regions adjacent a first major substrate surface 3 arranged on opposing sides of an insulated trenched-gate 6 and field plate 8. As shown in FIG. 1, current flow is both lateral and vertical, being vertical from source to channel, lateral beneath the trench into the drain drift region, and vertical from the drift region to the drain. Current flow, in the illustrated striped cell comprising a mirror-image transistor pair, is thus from the source regions 4b of the respective transistors, at the opposite sides of the trench pair, to the common drain region 4a between the trench pair.

It will be appreciated that, in practice, a power device having the above-described striped configuration typically comprises multiple striped cells 100 formed from transistor pairs. In the described arrangement, each cell comprises a transistor pair with a common drain region therebetween and each transistor in a transistor pair shares a common source region with a transistor of the adjacent transistor pair.

Alternatively, although less convenient to manufacture, the transistor need not be formed in mirror image pairs.

The power transistor structure of the above-described embodiment of the present invention thus benefits from a lateral arrangement, which is more compatible with CMOS processing, whilst utilizing a trench-gate and field plate to allow device scaling. The field plate provides the benefit of a Reduced Surface Field (RESURF) structure, thus improving the device characteristics such as breakdown voltage, specific on-resistance and their trade-off.

Moreover, the device structure may be formed in a process compatible with CMOS processing. One such process is described below with reference to FIGS. 3a to 3m.

FIGS. 3a to 3m show the steps of a method for fabricating a power semiconductor device, and concurrently a CMOS semiconductor device, integrated on the same substrate, in accordance with one embodiment of the present invention. For the purposes of illustration of each stage in the method, a portion of the power semiconductor device (herein the “power semiconductor region”) is shown on the left hand side and a portion of the CMOS device (herein the “CMOS region”) is shown on the right hand side of each drawing.

In the illustrated embodiment, a p-type semiconductor substrate 1, typically monocrystalline silicon, having an n-type well 5 in an upper part of the substrate 1, adjacent a first major surface 3, is utilized for the integrated power device. The n-type well 5 may be formed by conventional techniques (e.g. by growing an n-type epitaxial layer on a p-type substrate or by implanting n-type dopants into the upper part of the p-type substrate). In addition, shallow trench isolation (STI) is formed at predefined locations in the CMOS region using conventional STI processing. These processing steps produce the stage illustrated by the cross sectional views of the power semiconductor and CMOS regions in FIG. 3a.

Next a hard mask 10 is formed over the first major surface 3 and patterned, in the power semiconductor region, using conventional techniques such as photolithography and etching. The patterned hard mask defines a pattern for the formation of trenches 11. Trenches are then formed by etching the substrate 1 to a first depth, so that the trenches 11 terminate in the n-well region, above the p-type substrate region. As the skilled person will appreciate, the etching process to form trenches 11 is conventional and may be selected according to the desired parameters. Typically, trenches having a depth of about 0.3 to 5 microns and a width of about 0.5 to 5 microns are formed with a spacing between the trenches 11 of about 0.2 to 3 microns using a dry etching technique such as reactive ion etching using HBr or SF₆. This leads to the stage illustrated in FIG. 3b, from which it is evident that the trenches 11 are formed only in the power semiconductor region, the hard mask 10 preventing etching of the substrate in the CMOS region (not shown).

An insulating layer of silicon dioxide 15, preferably formed using TEOS (tetraethoxysilane), is then blanket deposited over the substrate and on the sidewalls and bottom of the trenches 11 in the power semiconductor region, as illustrated by FIG. 3c. The TEOS is typically about 50 to 800 nm in thickness and forms an oxide liner for the trenches 11 in the power semiconductor region. As will be appreciated from the following description, the silicon dioxide layer 15 insulates the field plate 8 from the trench walls in the final device structure in the power semiconductor region.

Next trenches 11 are filled with (doped) polysilicon 17 by depositing a first layer of polysilicon 17 over the substrate as shown in FIG. 3d. The polysilicon may be rendered conductive by doping the polysilicon with an active n-type or p-type dopant either during or preferably after deposition thereof. The doped polysilicon layer 17 within the trenches 11 in the power semiconductor region will form the field plate 8 of the final structure of transistor 2.

As shown in FIG. 3d, at this stage, the CMOS region has three layers comprising hard mask 10, TEOS 15 and (doped) polysilicon 17 on the first major surface thereof. These three layers are removed in the next stage by conventional techniques (e.g. polysilicon and oxide etch back and/or planarisation and hard mask removal) as shown in FIG. 3e, so that the CMOS region is returned to its starting state (c.f. FIG. 3a). These processing steps produce polysilicon-filled, insulated trenches 19, which are substantially flush with the first major surface 3 of the substrate 1 in the power semiconductor region, as shown in FIG. 3e.

P-type dopants are next introduced into predefined areas of the power semiconductor and CMOS regions to form p-wells 21 which extend to a predetermined depth (the aforementioned third depth) as shown in FIG. 3f. The p-wells 21 are typically formed using conventional dopant implantation techniques using an implantation mask (not shown). Alternatively, a controlled/directional implantation may be used, as described below with reference to FIG. 8. The implantation energy and dose used to form the p-well regions 21 are chosen according to the desired parameters of the final device including the depth of the gate 6, the desired threshold voltage and the gate oxide thickness. The p-wells 21 in the power semiconductor region form the body (channel) region 7 of the power semiconductor device structure. As the skilled person will appreciate, the p-wells 21 may be formed at any appropriate stage in the fabrication process. For example, the p-wells may be implanted after the stage shown in FIG. 3g, described below, which would ensure alignment with the gate 6.

A first layer of photoresist 23 is then provided over the first major surface 3 of the substrate 1 and patterned to define a mask. The patterned mask exposes the TEOS 15 on the first sidewalls of the trenches 11, i.e. the sidewalls of the trenches that are adjacent a p-well 21, whilst protecting the TEOS on the second sidewalls of the trenches that are not adjacent p-wells 21. As shown in FIG. 3g, the edges of patterned photoresist 23 are positioned on the polysilicon 17, so that photoresist 23 covers all areas of oxide that need to be protected. A portion of the exposed TEOS 15 is then removed by performing an etch, which removes the exposed TEOS 15 down to substantially the same depth as the p-well 21 to form sub-trenches 25 for a vertical trench-gate, as shown in FIG. 3g. The etch is carried out using conventional techniques. Preferably, a wet etch is performed, for example using a solution of HF as an etchant, for a predetermined time to achieve the desired depth, which is typically about 1 micron. Alternatively, a dry etch may be performed, followed by a wet etch to remove any residual oxide spacers on the trench sidewalls.

As previously mentioned, in some embodiments, the gate 6 and p-body region 7 extend to substantially the same depth (the third depth) from the surface of the substrate. Thus, it is desirable to align the sub-trench 25, in which the gate 6 will be formed, with the p-well 21 which will form the p-body region 7. Thus the etching step to form the sub-trenches 25 and the implantation step to form the p-wells 21 should be controlled to ensure this alignment.

The photoresist 23 is then removed and a first thin layer of oxide 29 is grown to a first thickness substantially less that the thickness of TEOS layer 15, for example of about 10 nm for operational gate voltages of up to 5V. The first thin oxide layer 29 is formed on the sidewalls of each of the sub-trenches 25. The first thin oxide layer 29 will form gate insulator 9 in the final power device structure and thus the first thickness corresponds to slightly less than a desired gate dielectric thickness. As shown in FIG. 3h, oxide is also concurrently grown on the top surface of the polysilicon 17 in the trenches and on the first major surface 3 of the substrate between the trenches 11 in the power semiconductor region, and over the CMOS region (not shown). As the skilled person will appreciate, it is also possible to form the first thin oxide layer 29 by depositing a layer of insulating material 29 (e.g. nitride, oxynitride or other higher-k dielectric) on the sidewalls and bottom of the sub-trenches 23.

A second layer of photoresist 27 is then formed over the structure and in the sub-trenches 25 and patterned, using conventional methods, to expose the CMOS region whilst protecting the power semiconductor region. The first thin oxide layer 29 formed in the CMOS region in the preceding step is then removed. Thereafter, the remainder of the second layer of photoresist 27 overlying the power semiconductor region is removed, and a second thin oxide layer 31 is grown to a thickness of about 1.5 to 6 nm, depending upon the desired gate operational voltages of the CMOS devices, on the first major surface 3 of the substrate in the CMOS region as shown in FIG. 3i. At the same time, the first thin oxide layer in the power semiconductor region is concurrently thickened, by oxide growth at a comparatively slow rate, to the desired gate oxide thickness for the power device. The second gate oxide layer 31 in the CMOS region forms the gate dielectric for the CMOS devices.

Subsequently, the remainder of the second layer of photoresist 27 overlying the power semiconductor region is removed and a second layer of polysilicon 33 is formed over the CMOS region and over and in the trenches of the power semiconductor region as shown in FIG. 3j. Typically, the second layer of polysilicon 33 is provided by depositing an in-situ doped layer conformally over the first major surface 3 of the substrate 1, thereby filling the sub-trenches 25. It will be appreciated that the polysilicon layer 33 may be doped at a later stage.

Thereafter a third layer of photoresist 35 is formed over the polysilicon layer 33. The photoresist 35 is then patterned using conventional techniques and the polysilicon 33 is etched to concurrently form polysilicon gate contacts 37 in the power semiconductor region and transistor gate electrodes in the CMOS regions to reach the stage shown in FIG. 3k. In particular, in the power semiconductor region the polysilicon layer 33 is etched back to gate oxide 29 on the first major surface 3 and polysilicon gate pads 37, defined by the photoresist pattern, are formed to connect to the vertical gates 33 (FIG. 2). In the CMOS region, the photoresist pattern defines the transistor gates so that the etching step forms the CMOS transistor gates 39.

Thereafter, the patterned layer of photoresist 35 is removed, and n-type dopants implanted into the upper surface 3 of the substrate to form shallow, lightly doped source/drain extensions in the CMOS region and shallow n+ doping regions to either side of the trenches 11 in the power semiconductor region, as shown in FIG. 31.

Spacers 41 are then formed on the sidewalls of the CMOS transistor gates 39, by conventional techniques, prior to implanting the main, heavily doped source/drain regions 4 of n-type dopant in both the power semiconductor and CMOS regions. As shown in FIG. 3m, this stage completes the structure of the power semiconductor device of the embodiment of the present invention of FIG. 1. Thereafter, standard CMOS processing may be performed, such as silicidation and back-end processing to complete the CMOS logic devices. In addition, to complete the power devices, a low-resistance connection may be provided to the p-body region 7 by implanting a heavily doped p-type contact 51 on the first major surface 3 of the substrate 1, as described below and shown in FIG. 5.

In another embodiment, the power semiconductor device structure of the present invention may be formed on a silicon on insulator (SOI) substrate. Referring to FIG. 4a, which shows the process at the stage corresponding to that shown in FIG. 3b, the trenches 11 of the active transistors 2 are etched into the silicon to a depth above the buried oxide layer 42, leaving sufficient silicon below the trench bottom for the n-well/drift region 5. In addition, an isolation trench 43 is concurrently etched through the STI at the boundary of the power semiconductor and CMOS regions, which extends down to the buried oxide layer 42.

Concurrent etching may be achieved by first etching the STI oxide selectively with respect to silicon, after patterning the hard mask 10 but before etching the trenches 11 in the silicon. By starting the etch of the isolation trench, in this way, the silicon etch of the active trench and the isolation trench may be completed concurrently. Alternatively, concurrent etching may be achieved by dry etching (e.g. HBr etch) using appropriate dimensions for the device trenches 11 and the isolation trenches 43. Since wider isolation trenches 43 will etch faster than narrower device trenches 11, it is possible to complete etching of the isolation trench (i.e. down to the buried oxide layer 42) whilst leaving sufficient silicon below the active trenches 11 for the formation of power transistor cells in accordance with the present invention.

The deep isolation trench 43, extending to the buried oxide layer 42, achieves complete dielectric isolation of the power semiconductor region from the CMOS region, as shown in FIG. 4b, which shows the completed isolation trench structure.

FIG. 5 is a cross section of an NMOS transistor cell 100, similar to FIG. 1, in accordance with a further embodiment of the present invention. In this embodiment, the structure of each transistor device 2 of the mirror symmetric pair differs from the embodiment of FIG. 1 merely in that the depth of the conductive gate 6 in the trench 11 is substantially the same as the depth of the field plate 8 in the trench 11. This arrangement is suitable for use for low voltage applications, particularly those below about 20V. For such low voltage applications, the electrical field shaping by the field plate is limited to below the drain, such that an edge termination is not necessary. In the illustrated embodiment, a heavily P+ doped connection 51 is also provided to the p-well, as is well known in the art. The skilled person will appreciate that the p-well connection 51 is typically also included in all the other embodiments of the present invention.

FIG. 6 is a cross section of an NMOS transistor cell 100, similar to FIG. 1. In this cell, the structure of each transistor device 2 of the mirror symmetric pair differs from the embodiment of FIG. 1 merely in that the gate 6 and field plate 8 are integrally formed, and thus the first thin insulating layer 29 between the gate 6 and field plate 8 is omitted. The formation of an integral gate and field plate is suitable for some applications, but it is generally not preferred due to increased gate capacitance.

The arrangement of FIG. 6 may be achieved by modifying the above-described process (FIGS. 3a-3m) as follows. After deposition of the thick TEOS layer 15, as shown in FIG. 3c, a thin anti-oxidizing layer, such as a nitride liner, is deposited. Thereafter, the process continues with forming the polysilicon layer 17 as shown in FIG. 3d, followed by the process steps of FIGS. 3e-3g. The etching step to form sub-trenches 25 (FIG. 3g) does not remove the nitride liner, and thus, in the subsequent step, the first thin oxide 29 is grown only on the bottom and first side walls of the trenches 11. At some time after the oxidation to form the gate insulator 9 (FIG. 3h), the nitride liner is selectively removed by wet etching, using techniques well known in the art. For instance, the nitride liner may be removed after the second oxidation to form the thin gate oxide 31 in the CMOS area (FIG. 3i). However, the nitride liner should be removed before the deposition of the second layer of polysilicon 33 (FIG. 3j). Thereafter, the process continues, as described with reference to FIGS. 3k to 3m, with the polysilicon gate 6 formed adjacent the field plate 8 without an insulating layer therebetween. Thus the gate 6 and the field plate 8 are integrally formed as a single electrode.

FIGS. 7a to 7c are cross sectional views of a power semiconductor region, similar to those of FIG. 3, showing an alternative technique for forming the p-body region 7 in accordance with another embodiment of the present invention. In the method of this embodiment, the step of FIG. 3f, i.e. the formation of the p-well 21 prior to the etching of the sub-trenches 25, is omitted. Instead, the method starts with the steps described in relation to FIG. 3, up to the stage shown in FIG. 3g. Next the first layer of photoresist 23 is stripped and a sacrificial protective layer 28 (e.g. oxide) is formed and patterned to correspond with the pattern of photoresist 23, to reach the stage shown in FIG. 7a. The protective layer 28 protects the CMOS region and parts of the power semiconductor region from the subsequent ion implantation. Then, boron ions are implanted into the upper surface 3 of the substrate by vapour phase doping or plasma immersion doping, as shown in FIG. 7b. The boron impurities are diffused at high temperature into the n-well 5 from the upper surface 3 of the substrate and the sub-trenches 25 from the first side of the trenches 11. This leads to the stage shown in FIG. 7c, with the depth of the uniformly doped p-well region 21, which forms the p-body 7, self-aligned with the depth of the sub trenches 25 which will contain the gate electrode 6.

In yet another alternative embodiment, instead of forming the n-well 5, which forms the drain drift region, as an epitaxial layer on a p-type substrate 1, the drain drift region may be formed by vapour phase doping or plasma doping, directly after the formation of the trenches 11 at the start of the method. Techniques for vapour phase or plasma immersion doping are well known to the skilled person and are similar to those described above in relation to the formation of the p-wells illustrated in FIGS. 7a to 7c. Alternatively, the n-well 5 may be formed by large tilted implantation, in which the ion beam is tilted at a large angle to the surface of the substrate, as shown in FIG. 8. Thus, directly after the formation of trenches 11, n-type dopants may be introduced through the trench sidewalls by large tilted implantation. In this alternative technique shown in FIG. 8, which may be employed in conjunction with appropriate trench aspect ratios, the n-type doping is confined to regions surrounding deep trenches in the power semiconductor region, without doping the CMOS region, and the n-well 5 thus formed is self-aligned with the trenches 11.

In the above-described embodiments, the drain region 4a of each transistor extends up to the edge of the trench 11 at the surface 3 of the substrate. It has been found that at high operating voltages, breakdown of the device can occur at the corners of the drain 4a. This can be avoided by increasing the thickness of the field plate insulating layer 15. This is however undesirable as it results in weaker capacitive coupling between the field plate 8 and the drift region 5 (especially important in the drift region left/right outsides near/under the gate) thus the drift region must be less doped and hence the specific on-resistance increases. In accordance with a further embodiment of the invention, this problem is alleviated by spacing the doped drain region 4a from the edge of the trench 11, as shown in FIG. 9. The resulting lower doped region between the drain and the trench can be depleted and therefore carry some potential.

In a further embodiment shown in FIG. 10, the drain region 4a is spaced from the trench 11 by a further trench 51 filled with an insulating material. The further trench has a depth less than that of the trench 11. This results in asymmetry of the oxide thickness on the drain side of the field plate. Preferably, the further trench 51 is etched and filled during the shallow trench isolation process required for the CMOS devices (before the deep trench 11 formation) and as described above with reference to FIG. 3a. However, it will be appreciated that the oxide-filled further trench 51 may be formed in a dedicated process step.

In order to further reduce the on-resistance of the hybrid transistor, the channel resistance can be reduced by increasing gate density through added gate trenches as shown in FIG. 11. It should be appreciated that FIGS. 11 and 12 show a pair of devices with the source and gates in the centre and the respective drains on the outside. Each transistor further comprises an auxiliary conductive gate 66 adjacent, and insulated from, the body region 7 at a side remote the conductive gate 6. The embodiment shown comprises an auxiliary gate 66 which is shared between two transistors. However, it will be appreciated that a single transistor can have one (or more) dedicated auxiliary gates.

In a further embodiment, multiple gates 66 can be implemented within the body region 7, as shown in FIG. 12. As can be seen, there is no gate within the trench 11 in this embodiment and the conductivity of the channel is controlled solely by the gate(s) on the side of the body region remote the trench 11.

It will be appreciated that there are many different permutations of gate arrangement both with and without gates located within the trench 11, whilst still falling within the scope of the invention. For those arrangements comprising one or more gates located outside of the trench 11, the (further) trenches can be photolithographically patterned in the substrate after the p-well (body region 7) implantation as described above in relation to FIG. 3f.

The above-described embodiments of the present invention have a striped cell configuration. Each transistor cell 100 comprises a pair of asymmetric transistors 2, arranged in a mirror image configuration to provide a symmetric cell 100. As the skilled person will appreciate, this symmetry ensures that, for high voltage applications, the electric field within the device, in use, is appropriately shaped, for instance to achieve an identical or uniform capacitive coupling effect between the field plate and the drift region. However, it is equally possible to preserve symmetry by forming the semiconductor device structure of the present invention in a square, hexagonal, circular or other symmetrical cell configuration.

By way of example, FIG. 13 shows a plan view of a power semiconductor region of an integrated circuit in accordance with another embodiment of the present invention. The illustrated power semiconductor region comprises a two by two array of square transistor cells 100. Unlike the striped cell embodiments, each cell 100 comprises a single NMOS power transistor 2 and, as will be appreciated from the following description, its main features are square-shaped, when viewed in plan. It will be appreciated that other embodiments may be formed from an array of any other number of such square transistor cells 100.

Each cell 100 has a square-shaped, shared n-type drain region 4a at its centre, adjacent the top surface 3 of the substrate 1. The drain region 4a is surrounded by a polysilicon-filled, insulated trench 11. A relatively thick field oxide layer 15 insulates the drain region 4a from the trench 11, on a first side (the inner side of the cell) of the trench 11. On the second side (the outer side of the cell) of the trench 11, an n-type source region 4b is formed at the top surface 3 of the substrate 1. The source region 4b is insulated from the trench 11 by a non-uniform insulating layer, as described below.

An insulated gate and field plate is provided in the trench 11 in accordance with the present invention. In particular, the trench 11 includes a conductive field plate 8, extending to a first depth within the trench 11, on the first side thereof, and insulated from the drain region 4a (and n-well/drain drift region 5) by the relatively thick field oxide 15. The trench further includes a conductive gate 6, extending in the trench 11 to a second depth which is less than or equal to the first depth, and insulated from the source region 4b (and p-body region 7) by a relatively thin gate dielectric layer 9. In the illustrated embodiment, the conductive gate 6 and field plate 8 are insulated from each other, in the trench 11, by an insulating later 29. P-body regions 7 (not shown) are formed to a depth substantially equal to the second, gate depth, beneath the source regions 4b on the second side (outside) of the trench 11, and the structure is formed in an n-well (not shown) which forms the drain drift region 5.

As the skilled person will appreciate, the cross section along line I-I of the square cell 100 is similar to the cross section of the striped cell embodiment of FIG. 1, except that the distance between the trenches 11 is typically greater due to the larger lateral dimension of the drain region 4a in the square cell configuration. In other embodiments, the square transistor cells 100 may have a cross section similar to the embodiment of FIG. 5 or 6.

The array of cells is surrounded by an oxide layer 55, having a field plate edge termination 57. It will be appreciated that any other suitable technique for providing an edge termination can be used.

The features of this embodiment, such as the materials, insulating layer thicknesses, and doping concentrations, are similar to the first embodiment and method of formation is similar to the described method illustrated in FIGS. 3a-3m.

The above-described embodiments utilize a field plate insulating layer 15 which is substantially uniform in thickness over the sidewalls of the trench 11. In a further embodiment, shown in FIG. 14, the oxide thickness is non-uniform, where t1<t2<t3. In order to provide a non-uniform liner 15, the etched trenches 11 of FIG. 3b are filled with oxide and planarised instead of the oxide deposition described above with reference to FIG. 3c. The trenches 11 are then etched into the oxide-filled trenches using photolithographic processing. This step determines the thickness of the field plate insulating layer 15 on the respective trench sidewalls. Further processing of the device will be apparent to the skilled person.

In summary, the present invention provides a power transistor having a vertical arrangement which permits further reductions in the scale and die area occupied by power devices in an integrated circuit. The arrangement can achieve low specific on-resistance similar to conventional vertical power devices. Furthermore, the arrangement permits a relatively short gate and longer field plate, thereby providing low channel resistance, higher output current per unit width and reduced capacitance, particularly in the case where the gate and field plate are isolated from each other. The arrangement can be manufactured using a process that is readily compatible with conventional CMOS processing, making it suitable for integrated circuit applications.

From reading the present disclosure, other variations and modifications will be apparent to the skilled person. Such variations and modifications may involve equivalent and other features which are already known in the art, and which may be used instead of, or in addition to, features already described herein.

Cells may be formed as individual asymmetric transistors for low voltage applications, such as below about 40-50V. For such low voltage applications, a uniform electric field across the structure is less essential than for higher voltages, where the uniform electric field resulting from cell symmetry is more critical.

Moreover, equivalent materials and process steps may be utilized instead of those described above.

Whilst the trenches have been depicted having a trench depth greater that trench width, this need not be the case in practice. Any suitable trench proportions may be used in conjunction with the present invention.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicant hereby gives notice that new claims may be formulated to such features and/or combinations of such features during the prosecution of the present application or of any further application derived therefrom.

1. A trench-gate semiconductor device comprising:
a semiconductor substrate having a first major surface;
a trench extending from the first major surface (3) into the substrate;
first and second impurity doped regions of a first conductivity type at respective first and second opposing sides of the trench adjacent the first major surface;
a body region of a second conductivity type, opposite to the first conductivity type, formed only below the first impurity doped region on the first side of the trench;
a drift region of the first conductivity type, below the body region and the second impurity doped region, the trench terminating in the drift region;
a conductive gate insulated from the body region by a gate insulator, and
a conductive field plate in the trench, the field plate extending into the trench parallel to the conductive gate to depth greater than or equal to the depth of the conductive gate, wherein the field plate is insulated from the drift region in the trench by a field plate insulating layer, and wherein the thickness of the field plate insulating layer is substantially greater than the thickness of the gate insulator.

2. A semiconductor device as claimed in claim 1, wherein the conductive gate is in an upper part of the trench adjacent the first side thereof, and the conductive field plate is adjacent to the conductive gate.

3. A semiconductor device as claimed in claim 1, wherein the thickness of the field plate insulating layer is in the range of about 50 to 800 nm.

4. A semiconductor device as claimed in claim 1, wherein the conductive gate extends to a depth from the first major surface that is substantially equal to the depth of the body region from the first major surface.

5. A semiconductor device as claimed in claim 1, wherein the second impurity doped region is spaced from the trench.

6. A semiconductor device as claimed in claim 5, wherein the second impurity doped region is spaced from the trench by a further trench filled with an insulating material, said further trench having a depth less than that of the trench.

7. A semiconductor device as claimed in any preceding claim, wherein the thickness of the field plate insulating layer on the second side of the trench is greater than on the first side of the trench.

8. A semiconductor device as claimed in claim 1, further comprising an auxiliary conductive gate adjacent, and insulated from, the body region at a side remote the conductive gate.

9. A method for making a semiconductor device, comprising:
forming a trench in a first major surface of a semiconductor substrate, the trench having first and second opposing sides;
lining the trench with a first insulating layer having a first thickness;
filling the trench with a conductive material;
forming first and second impurity doped regions of a first conductivity type adjacent the first major surface at the respective first and second sides of the trench;
forming a body region of a second conductivity type, opposite to the first conductivity type, only on the first side of the trench, the body region extending to a first predetermined depth from the first major surface.
forming a sub-trench extending to a second predetermined depth from the first major surface and having a first sidewall adjacent the body region;
lining the first sidewall of the sub-trench with a second insulating layer having a second thickness, which is substantially less that the first thickness, and
filling the sub-trench with a conductive material.

10. A method as claimed in claim 9, wherein the sub-trench is formed within the trench by removing a portion of the first insulating layer from only the first side of the trench, and wherein the first sidewall of the sub-trench is at the first side of the trench and a second sidewall is adjacent the conductive material.

11. A method as claimed in claim 9, wherein the second predetermined depth is substantially the same as the first predetermined depth.

12. A method as claimed in claim 9, wherein the step of forming the body region is performed before the step of forming the sub-trench.

13. A method for fabricating a power integrated circuit comprising a power device and at least one other semiconductor device, using the method as claimed in claim 9.
